(19) United States
(12) Patent Application Publication
(10) Pub. No.: US 2008/0026521 A1
(43) Pub. Date: Jan. 31, 2008

(54) Method for manufacturing a transistor of a semiconductor device

(75) Inventor: Woo Young Chung, Yongin-si (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: HYNIX SEMICONDUCTOR INC.

(21) Appl. No.: 11/808,664

(22) Filed: Jun. 12, 2007

(30) Foreign Application Priority Data
Jul. 28, 2006 (KR) 10-2006-0071546

(51) Int. Cl. H01L 21/8238

(52) U.S. Cl. 438/217; 257/E21.632

(57) ABSTRACT

A method for manufacturing a transistor of a semiconductor device is provided. The method includes the steps of: forming a gate over a semiconductor substrate including an NMOS transistor region and a PMOS transistor region; forming a photoresist pattern to open the gate of the PMOS transistor region; forming a first Lightly Doped Drain (LDD) region in the semiconductor substrate on both sides of the gate of the PMOS transistor region; forming a second LDD region in the semiconductor substrate on both sides of the gate of the PMOS transistor region; forming a gate spacer at sidewalls of the gate; and forming a junction region in the semiconductor substrate on the both sides of the gate spacer.

### RELATED APPLICATIONS

The present application claims the benefit of priority to Korean patent application number 10-2006-0071546, filed on Jul. 28, 2006, which is incorporated herein by reference in its entirety.

### BACKGROUND

The present invention generally relates to a method for manufacturing a semiconductor device, and more specifically, to a method for manufacturing a transistor of a semiconductor device.

Generally, a bit line sense amplifier senses and amplifies data on bit lines to output data into a data bus.

The bit line sense amplifier requires high sensitivity, high speed, a broad power voltage operation range, low power consumption, and a small area.

The bit line sense amplifier includes a PMOS transistor and an NMOS transistor which are connected with a latch type.

Specifically, the bit line sense amplifier includes transistors having a low threshold voltage for low power consumption and high sensitivity.

An impurity-implanting process of the transistors of the bit line sense amplifier is performed similar to that of peripheral transistors.

However, it is difficult for bit line sense amplifiers to scale down the transistors, and to sense and amplify data stored in cells by low capacitance.

A threshold voltage of the PMOS transistor of the bit line sense amplifier is changed depending on the thickness of a gate spacer.

The thickness of the gate increases towards the wafer edge so that there is a large difference in the threshold voltage in the wafer.

Additionally, buried channel and effective channel effects are increased not by a bar-type transistor but by a ring-type transistor to have a large fluctuation of the threshold voltage.

The PMOS transistor of the latch-type bit line sense amplifier has a higher sensitivity than that of a general transistor of a peripheral circuit region which has a low threshold voltage.

### SUMMARY

Embodiments of the present invention are directed at providing a method for manufacturing a transistor of a semiconductor device which includes forming a Lightly Doped Drain (LDD) region in a PMOS transistor to reduce fluctuation of a threshold voltage by a thickness change of a gate spacer.

Consistent with an embodiment of the present invention, a method for manufacturing a transistor of a semiconductor device comprises the steps of: forming a gate over a semiconductor substrate including an NMOS transistor region and a PMOS transistor region; forming a photoresist pattern to open the gate of the PMOS transistor region; forming a first Lightly Doped Drain (LDD) region in the semiconductor substrate on both sides of the gate of the PMOS transistor region; forming a second LDD region in the semiconductor substrate on both sides of the gate of the PMOS transistor region; forming a gate spacer at sidewalls of the gate; and forming a junction region in the semiconductor substrate oh the both sides of the gate spacer.

The photoresist pattern is formed to have an interval ranging from 50 to 100 μm with the gate formed at the edge of the PMOS transistor region. The step of forming the first LDD region is performed by a C-halo ion-implanting process with As+. As+ is ion-implanted with a dose of 1E12±10%/cm² and energy ranging from 60 to 80 keV. The ion-implanting inclination angle in this step ranges from 10 to 20° toward the vertical direction of the semiconductor substrate. The step of forming the second LDD region is performed with BF2+. BF2+ is ion-implanted with a dose of 1E12±10%/cm² and energy ranging from 10 to 20 keV. The ion-implanting inclination angle in this step ranges from 0 to 5° toward the vertical direction of the semiconductor substrate.

### BRIEF DESCRIPTION OF THE DRAWINGS

FIGS. 1a and 1b are plane diagrams illustrating a semiconductor device consistent with an embodiment of the present invention.

FIGS. 2a and 2b are diagrams illustrating a Lightly Doped Drain (LDD) region formed in an NMOS transistor consistent with an embodiment of the present invention.

FIGS. 3a and 3b are diagrams illustrating a photoresist pattern consistent with an embodiment of the present invention.

FIGS. 4a and 4b are diagrams illustrating a third LDD region formed in a PMOS transistor consistent with an embodiment of the present invention.

FIGS. 5a and 5b are diagrams illustrating a fourth LLD region formed in the PMOS transistor.

FIGS. 6a and 6b are diagrams illustrating gate spacers formed in the gate of the NMOS transistor and the gate of the PMOS transistor.

FIG. 7 is a graph illustrating the change of the threshold voltage.

FIG. 8 is a graph illustrating a Drain Induced Barrier Lowering (DIBL) effect.

FIG. 9 is a cross-sectional diagram illustrating the PMOS transistor consistent with an embodiment of the present invention.

### DETAILED DESCRIPTION

Embodiments consistent with the present invention will be described in detail with reference to the accompanying drawings.

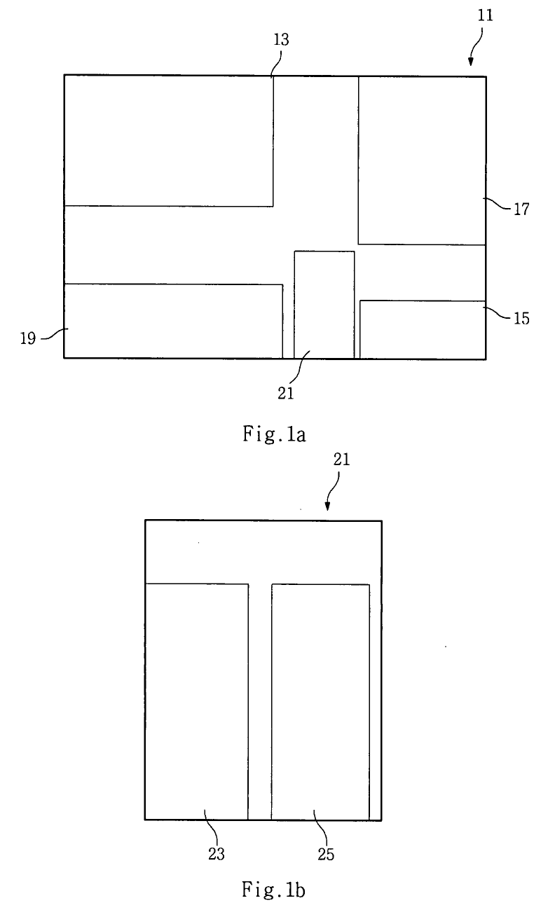

FIGS. 1a and 1b are plane diagrams illustrating a semiconductor device consistent with an embodiment of the present invention.

A column decoder 17, a row decoder 19, and a bit line sense amplifier 21 are formed over a semiconductor substrate 11 where a peripheral circuit region 13 and a cell region 15 are defined. Bit line sense amplifier 21 may be a latch-type sense amplifier.

FIG. 1b is an enlarged plane diagram illustrating bit line sense amplifier 21 of FIG. 1a.

Bit line sense amplifier 21 includes an NMOS transistor 23 and a PMOS transistor 25.

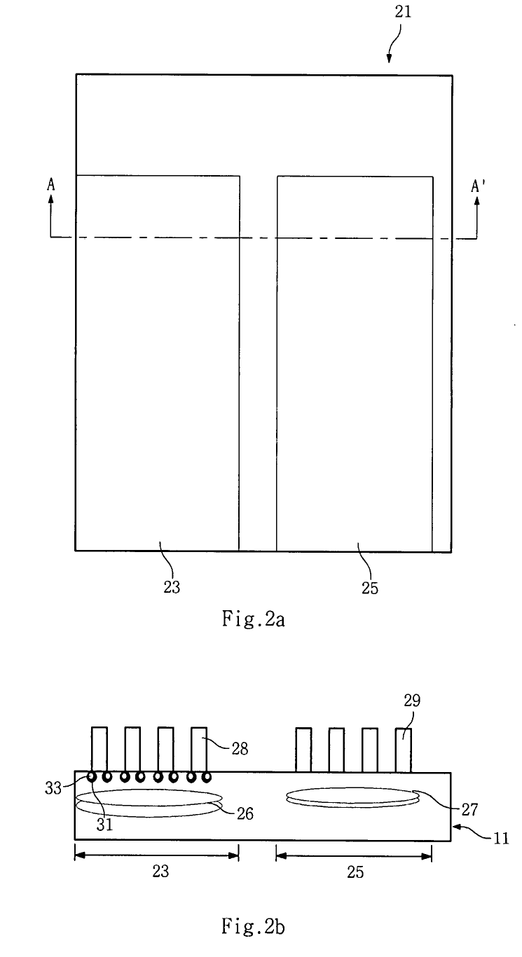

FIGS. 2a through 6b are diagrams illustrating a method for manufacturing a transistor consistent with an embodiment of the present invention. NMOS transistor 23 and PMOS transistor 25 in the latch-type bit line sense amplifier 21 are described.

FIGS. 2a and 2b are diagrams illustrating a Lightly Doped Drain (LDD) region formed in NMOS transistor 23. FIG. 2a is a plane diagram illustrating bit line sense amplifier 21, and FIG. 2b is a cross-sectional diagram taken along A-A′ of FIG. 2a.

A device separating film (not shown) is formed which defines an active region (not shown) in semiconductor substrate 11 including an NMOS transistor 23 region and a PMOS transistor 25 region.

A well ion-implanting process is performed on semiconductor substrate 11 to form well regions 26 and 27.

Gates 28 and 29 are formed in NMOS transistor 23 and PMOS transistor 25 over semiconductor substrate 11.

A first ion-implanting process of low concentration is performed on semiconductor substrate 11 on both sides of gate 28 of NMOS transistor 23 to form a first Lightly Doped Drain (LDD) region 31.

A second ion-implanting process of low concentration is performed on semiconductor substrate 11 on both sides of gate 28 of NMOS transistor 23 to form a second LDD region 33.

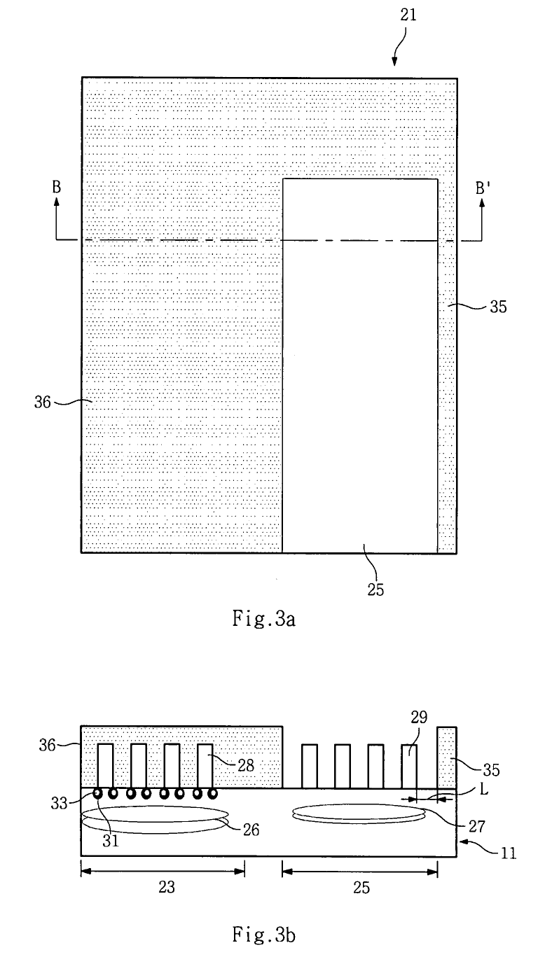

FIGS. 3a and 3b are diagrams illustrating a photoresist pattern to open the PMOS transistor 25 region. FIG. 3a is a plane diagram illustrating bit line sense amplifier 21, and FIG. 3b is a cross-sectional diagram taken along B-B′ of FIG. 3a.

A photoresist film is deposited over semiconductor substrate 11 shown in FIG. 2b.

The photoresist film is etched by a photo-etching process with a mask to open the PMOS transistor 25 region, thereby obtaining photoresist patterns 35 and 36.

Photoresist pattern 35 is formed to have an interval L between photoresist pattern 5 and gate 29 ranging from 50 to 100 μm with gate 29 formed at the edge of the PMOS transistor 25 region.

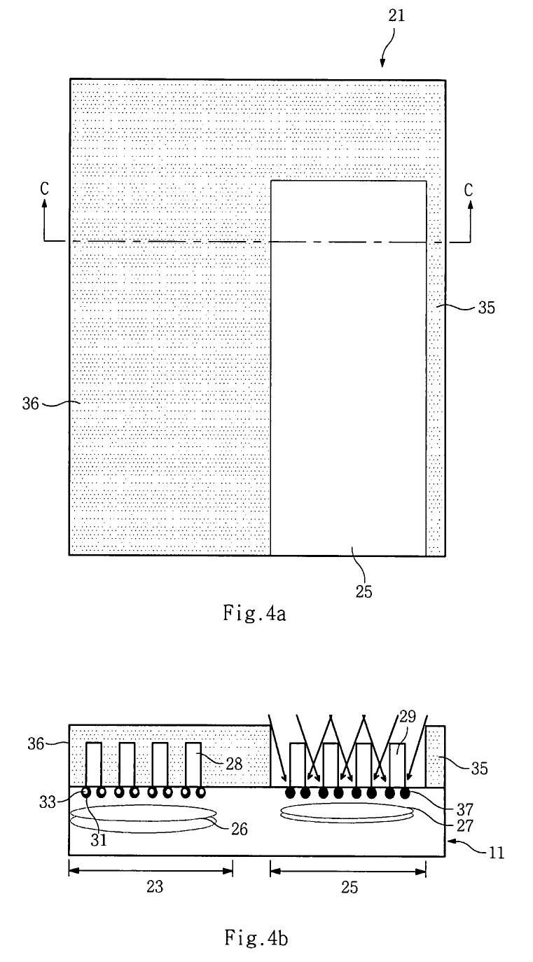

FIGS. 4a and 4b are diagrams illustrating a third LDD region formed in PMOS transistor 25. FIG. 4a is a plane diagram illustrating bit line sense amplifier 21, and FIG. 4b is a cross-sectional diagram taken along C-C′ of FIG. 4a.

A third ion-implanting process is performed on semiconductor substrate 11 on both sides of gate 29 of PMOS transistor 25 to form a third LDD region 37.

The third ion-implanting process is performed by a C-halo ion-implanting process with As+. The inclination angle ranges from about 10 to 20° towards the vertical direction of semiconductor substrate 11.

As+ is ion-implanted with a dose of about 1E12±10%/cm² and energy ranging from about 60 to 80 keV.

The third ion-implanting process is performed so that the threshold voltage of PMOS transistor 25 is not affected by the thickness of the gate spacer.

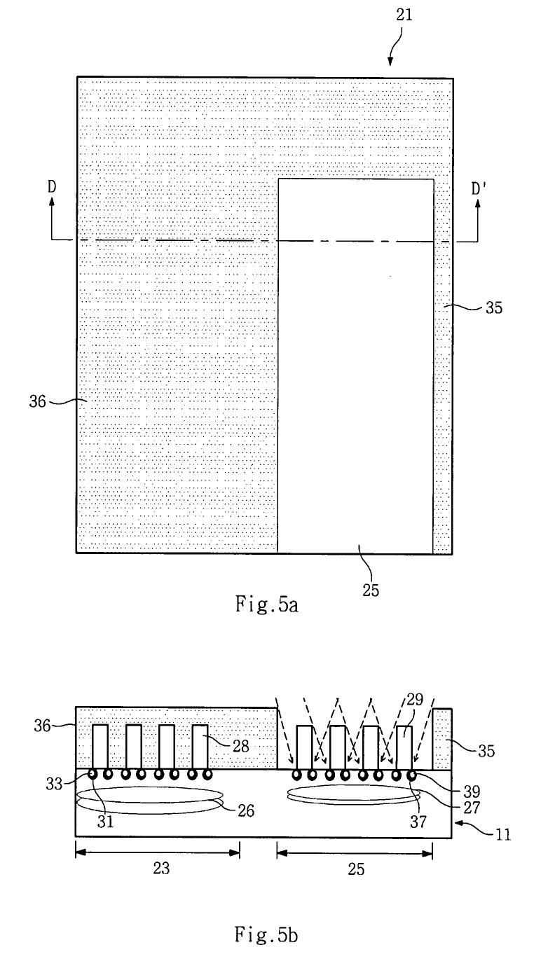

FIGS. 5a and 5b are diagrams illustrating a fourth LDD 39 region formed in PMOS transistor 25. FIG. 5a is a plane diagram illustrating-bit line sense amplifier 21, and FIG. 5b is a cross-sectional diagram taken along D-D′ of FIG. 5a.

A fourth ion-implanting process is performed on semiconductor substrate 11 on both sides of gate 29 of PMOS transistor 25 to form a fourth LDD region 39.

The fourth ion-implanting process is performed with BF2+, and the inclination angle ranges from about 0 to 5° toward the vertical direction of semiconductor substrate 11.

BF2+ is ion-implanted with a dose of about 1E13±10%/cm² and energy ranging from about 10 to 20 keV.

Fourth LDD region 39 is formed to reduce channel resistance caused by third LDD region 37.

After forming fourth LDD region 39, photoresist patterns 35 and 36 are removed.

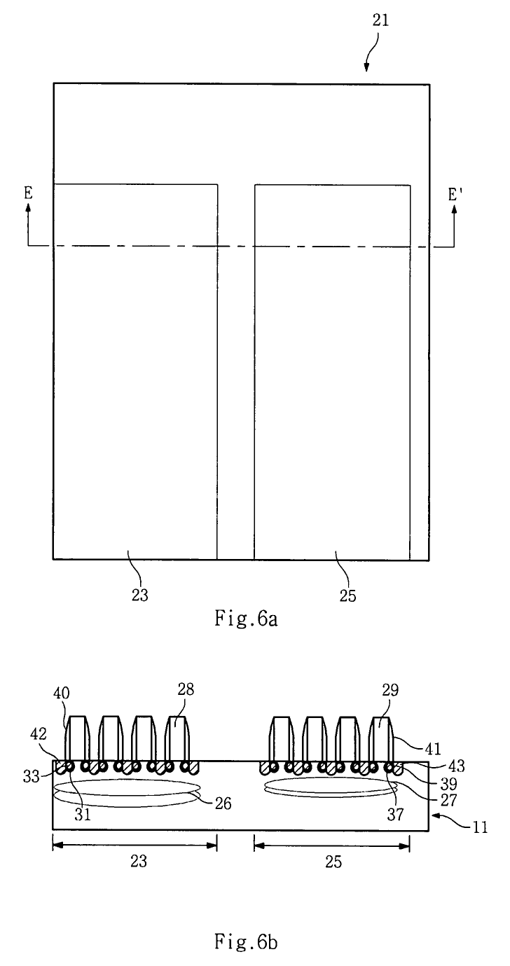

FIGS. 6a and 6b are diagrams illustrating gate spacers 40 and 41 formed in gate 28 of NMOS transistor 23 and gate 29 of PMOS transistor 25. FIG. 6a is a plane diagram illustrating bit line sense amplifier 21, and FIG. 6b is a cross-sectional diagram taken along E-E′ of FIG. 6a.

A nitride film is formed over semiconductor substrate 11 of FIG. 5b. The resulting structure is blanket-etched to form gate spacers 40 and 41 at sidewalls of gate 28 of NMOS transistor 23 and gate 29 of PMOS transistor 29.

A fifth ion-implanting process is performed on semiconductor substrate 11 on both sides of gate spacers 40 and 41 to form junction regions 42 and 43.

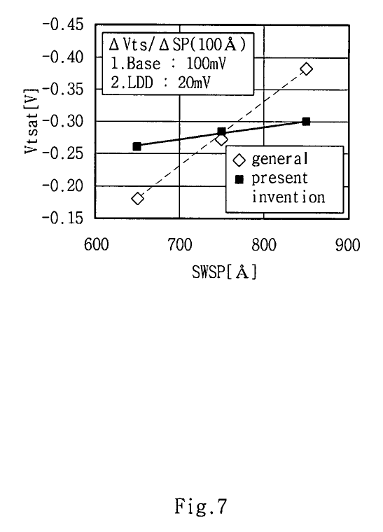

FIG. 7 is a graph illustrating the change of the threshold voltage in a saturated state depending on the thickness of gate spacer 41 of PMOS transistor 25.

In PMOS transistor 25, the threshold voltage Vtsat increases about 0.04V in the saturated state when the thickness SWSP of gate spacer 41 changes from 650 to 850 Å. However, in case of general PMOS transistors, the threshold voltage increases about 0.2V.

In other words, the fluctuation of the threshold voltage Vtsat in the saturated state depending on the thickness SWSP of gate spacer 41 in PMOS transistor 25 is less than that of general PMOS transistors.

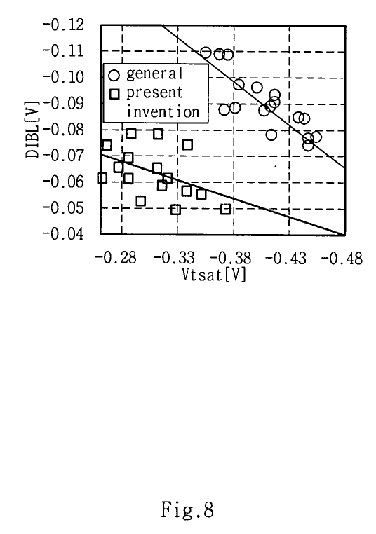

FIG. 8 is a graph illustrating a Drain Induced Barrier Lowering (DIBL) effect depending on the fluctuation of the threshold voltage in the saturated state in PMOS transistor 25.

When the threshold voltage Vtsat is −0.38V in the saturated state, the DIBL effect of PMOS transistor 25 is improved by about 45 mV compared with that of general PMOS transistors.

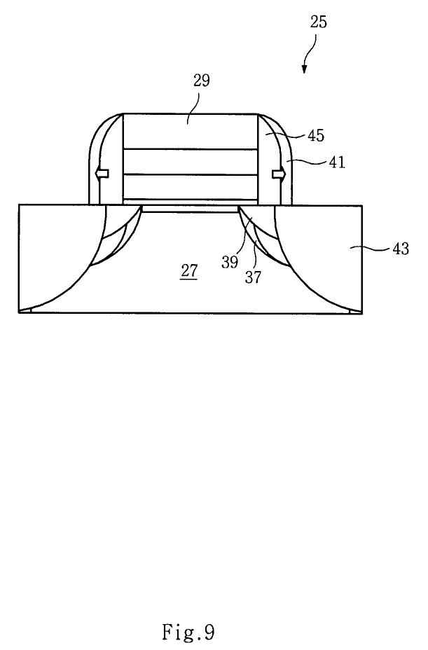

FIG. 9 is a cross-sectional diagram illustrating PMOS transistor 25 consistent with an embodiment of the present invention.

Although the thickness of gate spacer 41 increases toward an arrow direction by third LDD region 37 and fourth LDD region 39 in PMOS transistor 25 in comparison with that of general PMOS transistors, the fluctuation of the threshold voltage Vtsat in the saturated state is shown to decrease in comparison with that of general PMOS transistors.

Although PMOS transistor 25 of the latch-type bit line sense amplifier 21 is described, the method for manufacturing a transistor consistent with an embodiment of the present invention can be applied to any cases using a PMOS transistor having a regular threshold voltage and high sensitivity.

As described above, a method for manufacturing a transistor consistent with an embodiment of the present invention includes forming an LDD region in a PMOS transistor to reduce fluctuation of a threshold voltage by changing the thickness of a gate spacer, thereby improving characteristics of the transistor.

The above embodiments of the present invention are illustrative and not limitative. Various alternatives and equivalents are possible. The invention is not limited by the lithography steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a transistor of a semiconductor device, the method comprising the steps of:
forming a gate over a semiconductor substrate including a NMOS transistor region and a PMOS transistor region;
forming a photoresist pattern to expose a portion of the gate formed over the PMOS transistor region;
forming a first Lightly Doped Drain (LDD) region in the semiconductor substrate on both sides of the portion of the gate formed over the PMOS transistor region;
forming a second LDD region in the semiconductor substrate on both sides of the portion of the gate formed over the PMOS transistor region;
forming a gate spacer at sidewalls of the gate; and
forming a junction region in the semiconductor substrate on the both sides of the gate spacer.

2. The method according to claim 1, wherein the photoresist pattern is formed to have an interval ranging from 50 to 100 μm with a portion of the gate formed at an edge of the PMOS transistor region.

3. The method according to claim 1, wherein the forming the first LDD region is performed by a C-halo ion-implanting process with As+.

4. The method according to claim 3, wherein the As+ is ion-implanted with a dose of about 1E12±10%/cm² and energy ranging from about 60 to 80 keV.

5. The method according to claim 1, wherein forming the first LDD region is performed with an ion-implanting inclination angle ranging from about 10 to 20° toward the vertical direction of the semiconductor substrate.

6. The method according to claim 1, wherein forming the second LDD region is performed with BF2+.

7. The method according to claim 6, wherein the BF2+ is ion-implanted with a dose of about 1E13±10%/cm² and energy ranging from about 10 to 20 keV.

8. The method according to claim 1, wherein forming the second LDD region is performed with an ion-implanting inclination angle ranging from about 0 to 5° toward the vertical direction of the semiconductor substrate.
